(19) United States
(12) Patent Application Publication
(10) Pub. No.: US 2024/0319581 A1
(43) Pub. Date: Sep. 26, 2024

(54) MATCH THE ABERRATION SENSITIVITY OF THE METROLOGY MARK AND THE DEVICE PATTERN

(71) Applicant: ASML NETHERLANDS B.V., Veldhoven (NL)

(72) Inventors: Duan-Fu Stephen HSU, Fremont, CA (US); Jialei TANG, San Jose, CA (US); Dezheng SUN, Palo Alto, CA (US)

(73) Assignee: ASML NETHERLANDS B.V., Veldhoven (NL)

(21) Appl. No.: 18/579,176

(22) PCT Filed: Jul. 15, 2022
(86) PCT No.: PCT/EP2022/069967

§ 371 Date: Jan. 12, 2024

Related U.S. Application Data
(60) Provisional application No. 63/231,596, filed on Aug. 10, 2021.

(51) Int. Cl. G03F 1/36; G03F 7/00

(52) U.S. Cl. CPC G03F 1/36; G03F 7/70508; G03F 7/706; G03F 7/70683; G03F 7/706831; G03F 7/706837

(57) ABSTRACT

Generating a design (e.g., a metrology mark or a device pattern to be printed on a substrate) that is optimized for aberration sensitivity related to an optical system of a lithography system. A metrology mark (e.g., a transmission image sensor (TIS) mark) is optimized for a given device pattern by matching the aberration sensitivity of the metrology mark with the aberration sensitivity of the device pattern. A cost function that includes the aberration sensitivity difference between the metrology mark and the device pattern is evaluated based on an imaging characteristic response (e.g., a critical dimension (CD) response to focus) obtained from a simulation model that simulates lithography. The cost function is evaluated by modifying the metrology mark until the cost function is minimized and an optimized metrology mark is output when the cost function is minimized.

### CROSS-REFERENCE TO RELATED APPLICATIONS

This application claims priority of U.S. application No. 63/231,596 which was filed on Aug. 10, 2021 and which is incorporated herein in its entirety by reference.

### TECHNICAL FIELD

The description herein relates to lithographic apparatuses and processes, and more particularly to determining mask pattern design technologies.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g., comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a wafer stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, microlithography is a central step in the manufacturing of ICs, where patterns formed on substrates define functional elements of the ICs, such as microprocessors, memory chips etc. Similar lithographic techniques are also used in the formation of flat panel displays, micro-electromechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC) in the design layout, or other methods generally defined as “resolution enhancement techniques” (RET).

### SUMMARY

In some embodiments, there is provided a non-transitory computer-readable medium having instructions that, when executed by a computer, cause the computer to execute a method for optimizing a metrology target in a mask design used in a lithography system. The method includes determining a first aberration sensitivity of a device pattern to a select optical parameter related to an optical system of a lithography system, wherein the device pattern corresponds to a target pattern to be printed on a substrate; determining a second aberration sensitivity of a metrology target to the select optical parameter, wherein the metrology target is used to assist in printing the device pattern on the substrate; and optimizing the metrology target by matching the first aberration sensitivity with the second aberration sensitivity to generate an optimized metrology target.

In some embodiments, there is provided a non-transitory computer readable medium having instructions that, when executed by a computer, cause the computer to execute a method for generating an aberration sensitive pattern in a mask design used in a lithography system. The method includes obtaining a first imaging characteristic response of a first portion of a given design to a select optical parameter, wherein the given design includes one of (a) a device pattern that corresponds to a target pattern to be printed on a substrate, or (b) a metrology target used in printing the device pattern on the substrate, the first imaging characteristic response being representative of a first aberration sensitivity of the first portion; obtaining a second imaging characteristic response of a second portion of the given design to the select optical parameter, the second imaging characteristic response being representative of a second aberration sensitivity of the second portion, wherein the first and second aberration sensitivities are related to an optical system of a lithography system; obtaining a specified aberration sensitivity data to which the first and second aberration sensitivities are to be matched; and optimizing the given design by matching the first aberration sensitivity and the second aberration sensitivity to the specified aberration sensitivity to generate an optimized pattern.

In some embodiments, there is provided a method for optimizing a metrology target in a mask design used in a lithography system. The method includes determining a first aberration sensitivity of a device pattern to a select optical parameter related to an optical system of a lithography system, wherein the device pattern corresponds to a target pattern to be printed on a substrate; determining a second aberration sensitivity of a metrology target to the select optical parameter, wherein the metrology target is used to assist in printing the device pattern on the substrate; and optimizing the metrology target by matching the first aberration sensitivity with the second aberration sensitivity to generate an optimized metrology target.

In some embodiments, there is provided a method for generating an aberration sensitive pattern in a mask design used in a lithography system. The method includes obtaining a first imaging characteristic response of a first portion of a given design to a select optical parameter, wherein the given design includes one of (a) a device pattern that corresponds to a target pattern to be printed on a substrate, or (b) a metrology target used in printing the device pattern on the substrate, the first imaging characteristic response being representative of a first aberration sensitivity of the first portion; obtaining a second imaging characteristic response of a second portion of the given design to the select optical parameter, the second imaging characteristic response being representative of a second aberration sensitivity of the second portion, wherein the first and second aberration sensitivities are related to an optical system of a lithography system; obtaining a specified aberration sensitivity data to which the first and second aberration sensitivities are to be matched; and optimizing the given design by matching the first aberration sensitivity and the second aberration sensitivity to the specified aberration sensitivity to generate an optimized pattern.

### BRIEF DESCRIPTION OF THE DRAWINGS

FIG. 1 shows a block diagram of various subsystems of a lithography system.

FIG. 2 shows a flow for a patterning simulation method, according to an embodiment.

FIG. 3A is a block diagram of a system for generating an aberration sensitive pattern, in accordance with one or more embodiments.

FIG. 3B shows optimization of continuous tone mask image to generate an optimized pattern, in accordance with one or more embodiments.

FIG. 3C shows various imaging characteristic responses of a pattern, in accordance with one or more embodiments.

FIG. 4A is a flow diagram of a method for generating an aberration sensitive pattern, in accordance with one or more embodiments.

FIG. 4B is a flow diagram of a method for optimizing an input pattern using a cost function, in accordance with one or more embodiments.

FIG. 5A is a block diagram of a system for optimizing a metrology mark to have a matching aberration sensitivity with a given device pattern, in accordance with one or more embodiments.

FIG. 5B shows imaging characteristic responses of a metrology mark and a device pattern, in accordance with one or more embodiments.

FIG. 5C shows a graph illustrating an imaging characteristic behavior of an optimized metrology mark in comparison with an imaging characteristic behavior of a device pattern for which the metrology mark is optimized, in accordance with one or more embodiments.

FIG. 5D shows optimization of continuous tone mask image to generate an optimized metrology mark, in accordance with one or more embodiments.

FIG. 6A is a flow diagram of a method for optimizing a metrology mark to have a matching aberration sensitivity with a given device pattern, in accordance with one or more embodiments.

FIG. 6B is a flow diagram of a method for optimizing a metrology mark using a cost function, in accordance with one or more embodiments.

FIG. 7 is a block diagram of an example computer system, according to an embodiment.

FIG. 8 is a schematic diagram of a lithographic projection apparatus, according to an embodiment.

FIG. 9 is a schematic diagram of another lithographic projection apparatus, according to an embodiment.

FIG. 10 is a more detailed view of the apparatus in FIG. 10, according to an embodiment.

FIG. 11 is a more detailed view of the source collector module SO of the apparatus of FIGS. 9 and 10, according to an embodiment.

### DETAILED DESCRIPTION

In lithography, a patterning device (e.g., a mask) may provide a mask pattern (e.g., mask design layout) corresponding to a target pattern (e.g., target design layout), and this mask pattern may be transferred onto a substrate by transmitting light through the mask pattern. However, due to various limitations, the transferred pattern may appear with many irregularities and therefore, not be similar to the target pattern. Some metrology targets or metrology marks (e.g., a transmission image sensor (TIS) mark used for aligning mask to a substrate table, an overlay (OVL) mark, an alignment mark, or another mark (fiducial) are used for monitoring or measuring aberration drift of an optical system (e.g., lens) of a lithographic system. These metrology marks are sensitive to aberrations of the optical system which can cause the printed patterns to have irregularities.

The measured aberration drift may be compensated by adjusting one or more optical parameters (e.g., depth of focus, dose, Zernike polynomial, or other optical parameter) in the lithographic system. Typically, a mask includes both device patterns (e.g., target patterns to be printed on a substrate) and metrology targets. Reducing aberration detected by the metrology marks may not always lead to improved device pattern printing, because metrology marks and device patterns may have different or mismatching aberration sensitivity trends and therefore, have different responses to the adjustments of the optical parameters.

Embodiments of the present disclosure provide mechanisms to achieve matching sensitivity between metrology targets (or metrology marks) with device patterns with respect to the optical system of a lithography system. A metrology mark can be optimized according to given device patterns, thereby minimizing the irregularities in printing the device pattern on the substrate caused due to a mismatch between the aberration sensitivity of the metrology mark and the device pattern. In some embodiments, a behavior of an imaging characteristic (e.g., critical dimension (CD), a pattern placement error (PPE), an edge placement error (EPE), or another imaging characteristic) of a design with respect to an optical parameter (e.g., focus, dose, Zernike, wavefront image, or other optical parameter) may be indicative of an aberration sensitivity of the design. In some embodiments, designing and optimizing a metrology mark involves computing a difference between an aberration sensitivity of a metrology mark and a device pattern, adjusting the metrology mark (modifying the dimensions of the metrology mark (e.g., increasing or decreasing CD), or adding assist features to, or removing assist features from, the metrology mark) to reduce the aberration sensitivity difference. In some embodiments, the sensitivity difference is included as a term in a cost function. The cost function is minimized to optimize the metrology mark. In some embodiments, minimizing the cost function, or in other words, optimizing the metrology mark may include iteratively adjusting the mark such that the aberration sensitivity difference between the metrology mark and the device pattern is minimized.

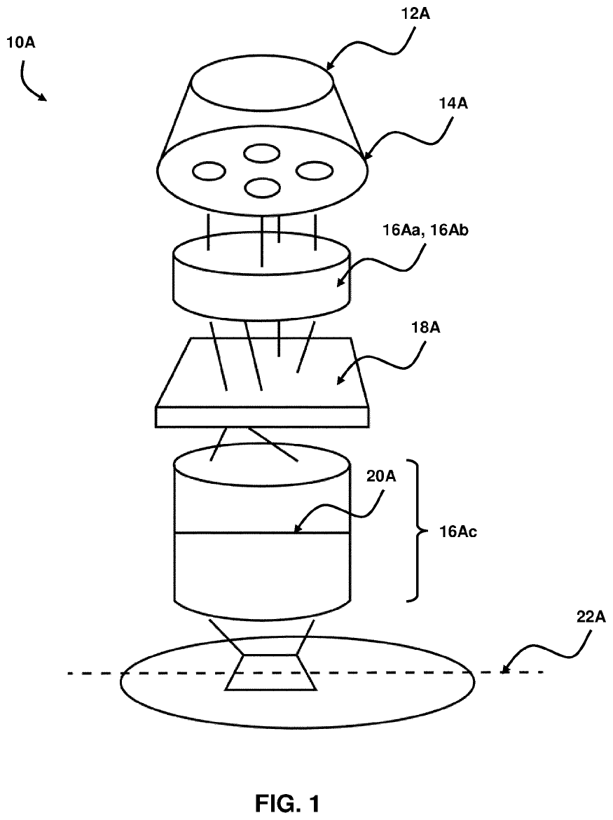

FIG. 1 illustrates a block diagram of various subsystems of a lithographic projection apparatus or a lithography system 10A, in accordance with one or more embodiments. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e., radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat. No. 5,229,872, which is incorporated herein by reference.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

Variables of a patterning process are called “processing variables.” The patterning process may include processes upstream and downstream to the actual transfer of the pattern in a lithography apparatus. A first category may be variables of the lithography apparatus or any other apparatuses used in the lithography process. Examples of this category include variables of the illumination, projection system, substrate stage, etc. of a lithography apparatus. A second category may be variables of one or more procedures performed in the patterning process. Examples of this category include focus control or focus measurement, dose control or dose measurement, bandwidth, exposure duration, development temperature, chemical composition used in development, etc. A third category may be variables of the design layout and its implementation in, or using, a patterning device. Examples of this category may include shapes and/or locations of assist features, adjustments applied by a resolution enhancement technique (RET), CD of mask features, etc. A fourth category may be variables of the substrate. Examples include characteristics of structures under a resist layer, chemical composition and/or physical dimension of the resist layer, etc. A fifth category may be characteristics of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). A sixth category may be characteristics of processes upstream of, or downstream to, pattern transfer in a lithographic apparatus, such as spin coating, post-exposure bake (PEB), development, etching, deposition, doping and/or packaging.

As will be appreciated, many, if not all of these variables, will have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

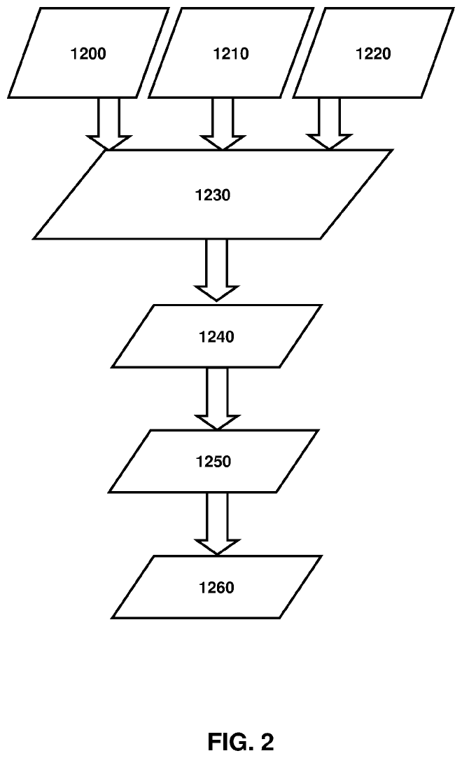

An exemplary flow chart for modelling and/or simulating parts of a patterning process is illustrated in FIG. 2. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (σ) settings as well as any particular illumination shape (e.g., off-axis radiation shape such as annular, quadrupole, dipole, etc.), where σ (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1230 can be simulated from the source model 1200, the projection optics model 1210 and the patterning device/design layout model 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model 1260. The post-pattern transfer process model 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process. The models can also be implemented using machine learning models.

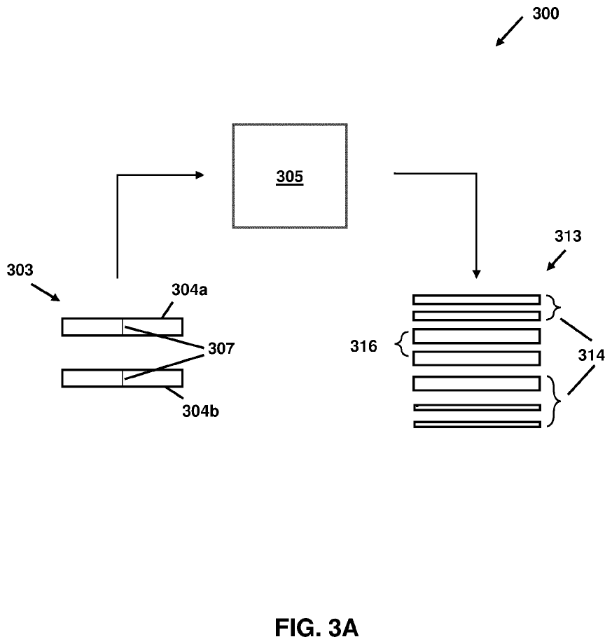

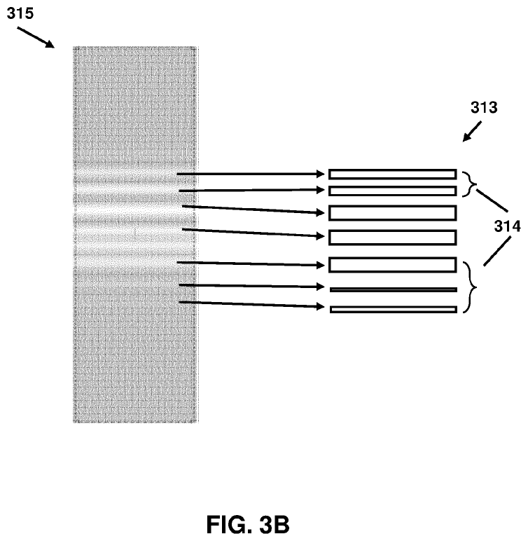

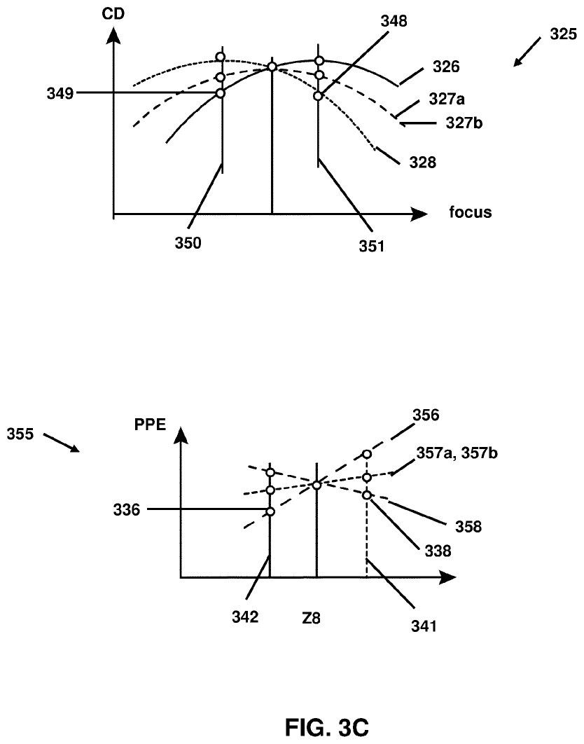

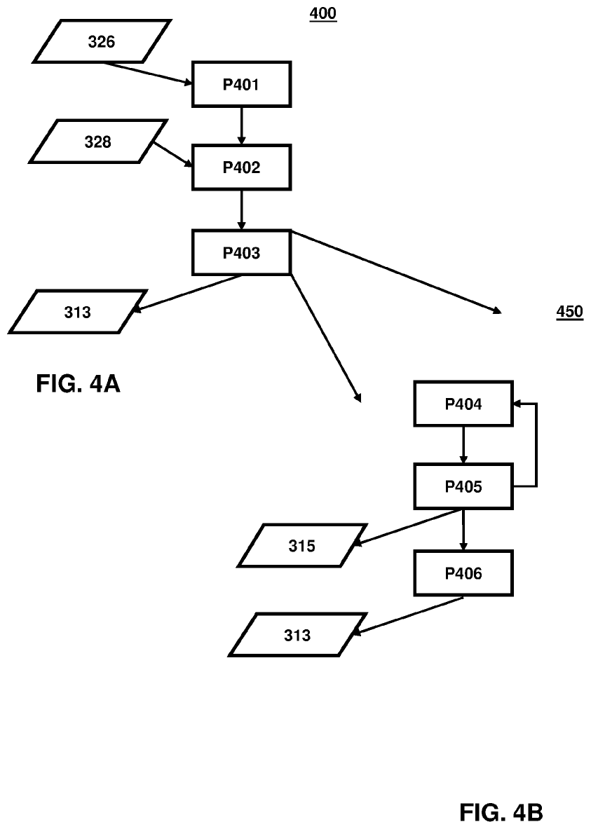

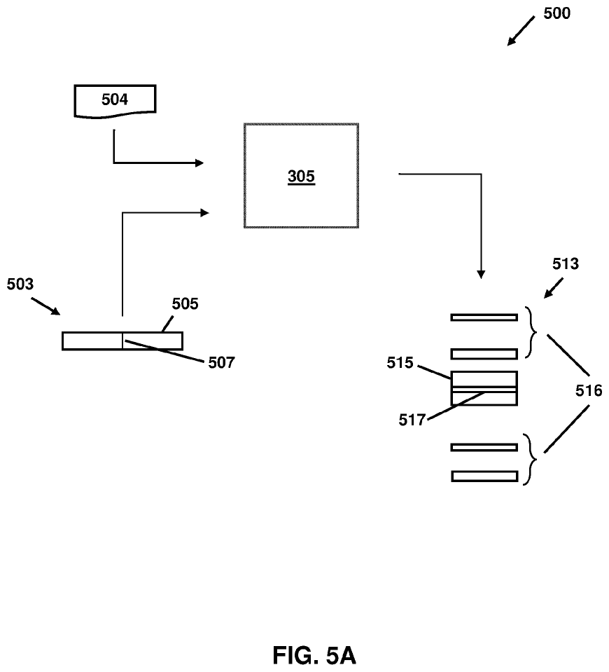

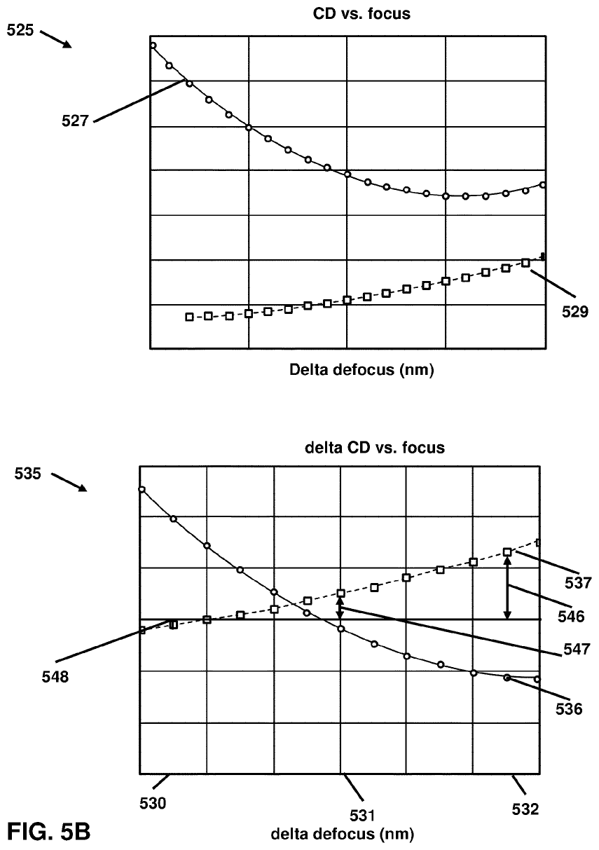

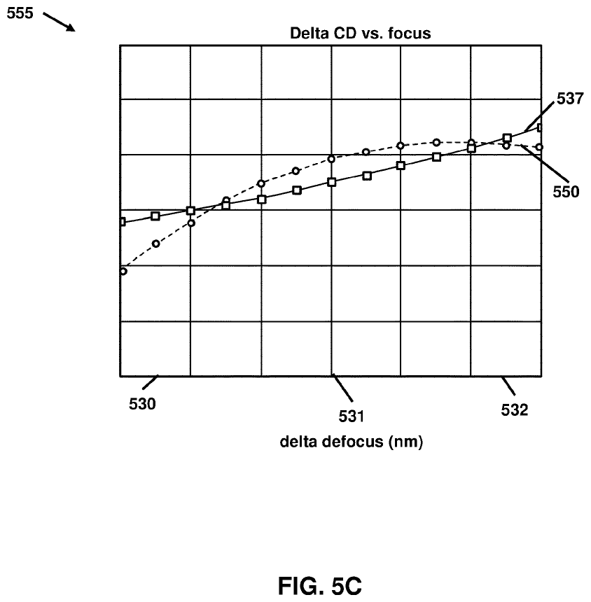

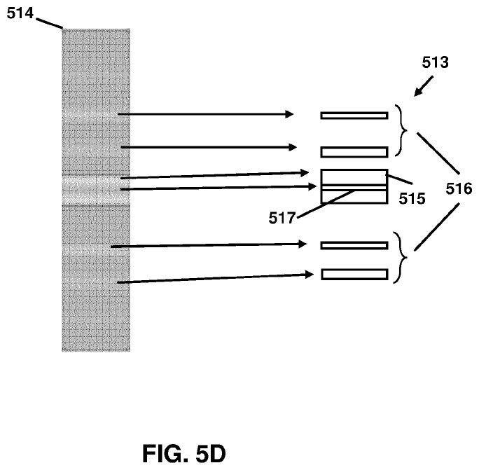

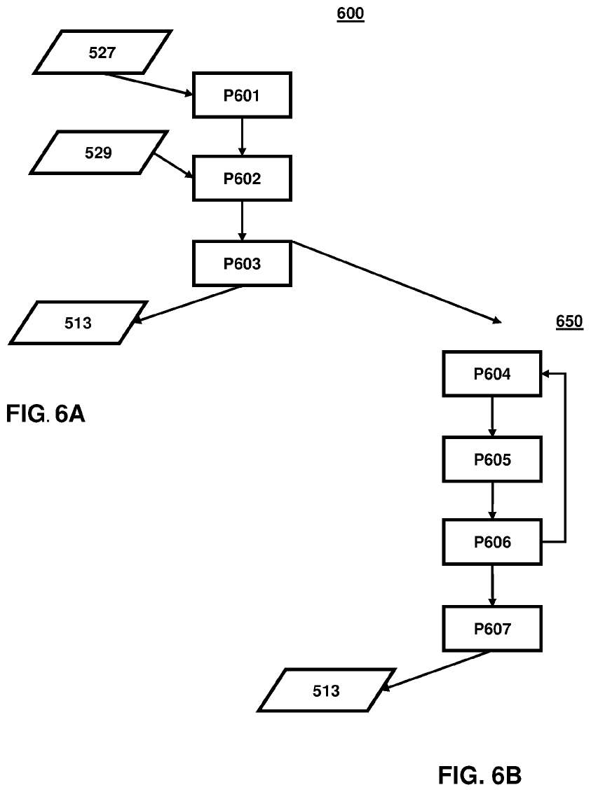

In the present disclosure, methods and systems are disclosed for optimizing a design with respect to aberration sensitivity related to an optical system of a lithography system. In a first example, a given input design is optimized for a specified aberration sensitivity (e.g., a specified imaging characteristic offset at a specified optical parameter, to which the imaging characteristic is to be matched). FIGS. 3A-3C and 4A-4B describe the generation of such an aberration sensitive design. In a second example, metrology targets or marks (e.g., a TIS mark, an OVL mark, an alignment mark, or another metrology mark) used to assist in printing a device pattern on a substrate, are generated or optimized to have matching aberration sensitivity with the device pattern. FIGS. 5A-5C and 6A-6B describe the optimization of such metrology marks.

In some embodiments, lithographic process is simulated on a design to obtain imaging characteristic behaviors of the design. The imaging characteristic behavior may be obtained for a specified optical parameter, e.g., focus, dose, Zernike, wavefront image, or other optical parameter of the optical system such as optics 14A, 16Aa-16Ac of lithography system 10A of FIG. 1. As an example, a CD response 326 to focus, which describes variation of CD of a base design 303 with different focus values, is illustrated in FIG. 3B. The CD response 326 to focus may be representative of an aberration sensitivity of the base design 303. Similarly, behavior of other imaging characteristics may be obtained for a specified optical parameter. As an example, a PPE response 356 to Zernike 8 (Z8), which is representative of behavior of a PPE of the base design 303 for different Z8 values is illustrated in FIG. 3C. The PPE response 356 to Z8 may be representative of aberration sensitivity of the base design 303. The imaging characteristic behavior may be obtained using a number of ways, for example, using simulation models such as an optics model, a source model or a resist model, which simulate a lithography system 10A or a patterning process, as described at least with reference to FIG. 2. In some embodiments, the imaging characteristic behavior may be derived from aerial images or continuous tone mask images resulting from the aforementioned one or more models. However, in some other embodiments, the imaging characteristic behavior may also be derived from any other images resulting from the one or more models, such as mask images, resist images, etch images, etc. The imaging characteristic behavior may be used in a cost function to optimize a given pattern for aberration sensitivity.

In some embodiments, generating or optimizing a design for aberration sensitivity involves computing a difference between an aberration sensitivity of an input design (which may be derived from the imaging characteristic behavior obtained as described above) and a specified aberration sensitivity (e.g., a specified aberration sensitivity or the aberration sensitivity of another design such as a device pattern), iteratively adjusting the design to reduce the aberration sensitivity difference. In some embodiments, the sensitivity difference is included as a term in a cost function. In some embodiments, the cost function is minimized to optimize the design. However, the present disclosure is not limited to any specific mathematic form of cost function.

The following paragraphs describe the generation of an optimized aberration sensitive design (e.g., a metrology mark or a device pattern) with reference to FIGS. 3A-3C and 4A-4B. FIG. 3A is a block diagram of a system 300 for generating an aberration sensitive pattern, in accordance with one or more embodiments. The system 300 includes a pattern optimizer 305 that is configured to optimize a given design in accordance with a specified aberration sensitivity (e.g., imaging characteristic offset at a specified optical parameter value). For example, the pattern optimizer 305 may optimize a base design 303 to generate an optimized design 313 having a CD response that matches with a given CD offset at a given focus value. The input provided to the pattern optimizer 305 may include the base design 303, an imaging characteristic (e.g., CD) associated with the base design 303 which is to be optimized, an optical parameter (e.g., focus) for which the imaging characteristic is to be optimized. The input may also include a specified aberration sensitivity to which the imaging characteristic of the base design 303 is to be optimized. For example, the specified aberration sensitivity may include one or more imaging characteristic offsets at one or more optical parameter values (e.g., CD offset_dfp 348, which is a first CD offset at a first focus value, dfp 351; and CD offset_dfn 349, which is a second CD offset at a second focus value, dfn 350 as illustrated in FIG. 3B). The base design 303 may include a metrology mark (e.g., a TIS mark, an overlay (OVL) mark, an alignment mark, or another suitable metrology mark), or a device pattern (e.g., a target pattern to be printed on a substrate). In some embodiments, the base design 303 may include two portions—a top pattern 304a and a bottom pattern 304b, and the top pattern 304a may be optimized for the first CD offset and the bottom pattern 304b may be optimized for the second CD offset.

In some embodiments, the pattern optimizer 305 may obtain a first CD response 327a of the top pattern 304a and a second CD response 327b of the bottom pattern 304b for a given measurement point 307 (e.g., using lithographic simulation on the base design 303). The CD responses are indicative of the aberration sensitivities of the respective patterns. The graph 325 of FIG. 3B illustrates the initial CD responses 327a and 327b. The initial CD responses 327a and 327b (prior to optimization) of both pattern portions may be obtained for a nominal condition (e.g., reference dose and focus values at which CD conforms to specified constraints). However, the initial CD responses may be obtained for conditions other than the nominal condition in some other embodiments.

The pattern optimizer 305 may compute or evaluate a cost function to determine a difference between the aberration sensitivity of top pattern 304a and the specified aberration sensitivity, and between the aberration sensitivity of the bottom pattern 30a and the specified aberration sensitivity, using the CD response of both pattern portions and the specified CD offsets at various focus values as follows:

$$( Equation 1 A )$$

$$Cost = {w}_{offset} [ {( {CD}_{dfp}^{CD \_ t} - {CD}_{offset - dfp} )}^{2} + {( {CD}_{dfn}^{CD \_ b} {CD}_{offset - dfn} )}^{2} ] + {NCEPE}^{2} + MRC penalty$$

where—w_{offset} is a weight factor added to adjust sensitivity,
CD_{dfp}^{CD_t} is CD of the top pattern 304a at dfp focus value,
CD_{offset-dfp} (348 in FIG. 3C) is the CD to which the CD of the top pattern 304a at dfp focus value has to be adjusted,
CD_{dfn}^{CD_b} is CD of the bottom pattern 304b at dfn focus value,
CD_{offset-dfn} 349 (348 in FIG. 3C) is the CD to which the CD of the bottom pattern 304b at dfn focus value has to be adjusted,
NCEPE is the EPE value at nominal condition, and
MRCpenalty is a penalty term associated with mask rule check, which is used to verify whether a mask design conforms to specified standards.

In the embodiments described in detail herein, the cost functions are designed to be minimized in order to optimize the design. However, it will be appreciated that the cost functions presented herein are exemplary; any other mathematical forms or more or less terms may be used without departing from the scope of the present disclosure.

The pattern optimizer 305 adjusts the base design 303 (e.g., dimension or geometry by modifying imaging characteristic such as CD) to reduce the cost, and evaluates the cost function with the adjusted values of CD (e.g., CD_{dfp}^{CD_t} or CD_{dfn}^{CD_b}). In some embodiments, reducing the cost includes reducing the term (CD_{dfp}^{CD_t}−CD_{offset-dfp}), which is representative of the difference between the aberration sensitivity of the top pattern and the specified aberration sensitivity, or reducing the term (CD_{dfn}^{CD_b}−CD_{offset-dfn}), which is representative of a difference between the aberration sensitivity of the bottom pattern and the specified aberration sensitivity. In some embodiments, the pattern optimizer 305 may also add assist features to, or remove assist features from, the base design 303 to reduce the cost function. In some embodiments, the lower the cost, the more optimized is the resulting design. The pattern optimizer 305 continues modifying the base design 303 and evaluating the cost function with adjusted CDs in an iterative manner, and outputs an optimized design 313 when the cost function is minimized. Alternatively, in some other embodiments, the optimized design is output when the cost function reaches a threshold value, or a threshold iteration. The optimized design 313 may have an aberration sensitivity matching the specified aberration sensitivity. For example, graph 325 depicts a) a CD response 328 of the optimized top pattern 304a in which the CD of the top pattern 304a is optimized for, or matches with, CD_{offset-dfp} 348 at focus value dfp 351, and b) a CD response 326 of the optimized bottom pattern 304b in which the CD of the bottom pattern 304b is optimized for, or matches with, the CD_{offset-dfn} 349 at focus value dfn 350. Further, in the optimized design 313, the pattern optimizer 305 has modified the CD of the pattern portion 316, which corresponds to top pattern 304a and bottom pattern 304b in the base design 303, and has added assist features 314 to the base design 303. Note that while the assist features 314 are added external to the pattern portion 316, in some embodiments, the assist features may be added either internal to the pattern portion 316 (e.g., between the two rectangles) or both internally and externally.

In some embodiments, the pattern optimizer 305 uses a continuous transmission mask (CTM) image (e.g., CTM image 315 illustrated in FIG. 3B) for optimizing the base design 303. In some embodiments, CTM technique is an inverse lithography solution that can generate a grayscale guidance map for a mask pattern (e.g., CTM image 315) for a given input pattern, process condition values (e.g., CD vs. focus value, CD vs. dose values, etc.), source information (e.g., pupil), or other such information. Based on the grayscale guidance map, assist features and modifications to main features of a design layout can be extracted. In an embodiment, such guidance map can be used to generated polygon shaped features (e.g., main features, assist features, SRAFs, SERIFs, etc. such as the optimized design 313). A CTM optimization process may involve optimization of grey scale values using a gradient descent, or other optimization methods, so that a performance metric (e.g., EPE) of a lithographic apparatus is improved. The CTM optimization process is performed with the above cost function in an iterative manner. In each iteration, the cost function is evaluated, the base design 303 is adjusted (e.g., dimensions of the top pattern 304a or bottom pattern 304b are modified, assist features added to or removed from the base design 303) to reduce the cost function. The CTM optimization process may continue until the cost function is minimized. After the cost function is minimized, the CTM image 315 is optimized, and the pattern optimizer 305 may extract the features from the CTM image 315 to generate the optimized design 313.

FIG. 4A is a flow diagram of an exemplary method 400 for generating an aberration sensitive design, in accordance with one or more embodiments.

At process P401, a first aberration sensitivity of a first portion of the base design 303 is obtained. In some embodiments, an imaging characteristic behavior to an optical parameter, such as the CD response to focus, is representative of the aberration sensitivity. For example, the initial CD response 327a may be representative of the first aberration sensitivity of the top pattern 304a to a focus parameter associated with an optical system of the lithography system. The imaging characteristic (e.g., a CD, a PPE, an EPE, or another imaging characteristic), or the optical parameter (e.g., focus, Zernike, wavefront image, or other optical parameter associated with the optical system), based on which the base design 303 may have to be optimized may be provided as input to the pattern optimizer 305. The imaging characteristic behavior may be obtained using a number of ways. For example, a lithographic process is simulated on a design to obtain imaging characteristic behaviors such as a CD response to focus, which describes how CD of a pattern varies for different focus values. In some embodiments, the lithographic process may be simulated using models such as an optics model, a source model or a resist model described at least with reference to FIG. 2. The input may also include a specified aberration sensitivity (e.g., imaging characteristic offset such as a CD offset at a particular optical parameter value) based on which the base design 303 may have to be optimized, or other such parameter.

At process P402, a second aberration sensitivity of a second portion of the base design 303 is obtained. For example, a CD response 327b, which is representative of the second aberration sensitivity for the bottom pattern 304b of the base design 303 may be obtained.

At process P403, the base design 303 is optimized by matching the first aberration sensitivity and the second aberration sensitivity to the specified aberration sensitivity to generate an optimized design 313. In some embodiments, the pattern optimizer 305 optimizes the base design 303 by adjusting the base design 303 (e.g., modifying imaging characteristics associated with the base design 303), evaluating a cost function to determine a difference between the first aberration sensitivity and the specified aberration sensitivity, and the second aberration sensitivity and the specified aberration sensitivity, and minimizing the cost function in an iterative manner, as described at least with reference to FIG. 3A above and FIG. 4B below. After the cost function is minimized, the pattern optimizer 305 outputs the optimized design 313.

FIG. 4B is a flow diagram of a method 450 for optimizing an input pattern using a cost function, in accordance with one or more embodiments. In some embodiments, the method 450 may be implemented as part of process P403 in method 400 of FIG. 4A. At process P404, a cost function is evaluated to determine a difference between the aberration sensitivity of top pattern 304a and the specified aberration sensitivity, and between the aberration sensitivity of the bottom pattern 304b and the specified aberration sensitivity. In some embodiments, the pattern optimizer 305 computes the cost function, such as the one indicated by Equation 1A above, based on the imaging characteristic behavior such as CD responses of the top pattern 304a and the bottom pattern 304b of the base design 303 and the CD offsets provided as input. For example, the cost function determines the difference between the aberration sensitivity of top pattern 304a and the specified aberration sensitivity at a focus value, dfp, using the term (CD_{dfp}^{CD_t}−CD_{offset-dfp}), and determines a difference between the aberration sensitivity of the bottom pattern 304b and the specified aberration sensitivity using the term (CD_{dfn}^{CD_b}−CD_{offset-dfn}).

At process P405, a CTM optimization process is performed. The CTM optimization process may involve optimization of grey scale values in the CTM image 315 corresponding to the base design 303 so that a performance metric (e.g., EPE) of a lithographic apparatus is improved. The CTM optimization process is performed with the above cost function in an iterative manner. In the CTM optimization process, the base design 303 is adjusted (e.g., dimensions of the top pattern 304a or bottom pattern 304b are modified, assist features added to or removed from the base design 303) to reduce the cost function.

The process P404 and P405 are performed iteratively until the cost function is minimized (e.g., cost does not reduce any more). During the evaluation, the pattern optimizer 305 may also adjust the weight of the cost function to adjust the sensitivity.

At process P406, after the cost function is minimized, the CTM image is processed to extract the features corresponding to the optimized design 313. For example, the CTM image 315 is processed to extract the features such as assist features 314 and pattern portion 316, which collectively form the optimized design 313.

Note that while the foregoing paragraphs describe optimizing a base design 303 that has two pattern portions, the base design 303 may have one or more pattern portions. Further, note that while the foregoing paragraphs describe optimizing the base design 303 for an imaging characteristic behavior, such as CD response, the base design 303 may be optimized for other imaging characteristic behavior as well. For example, the base design 303 may be optimized for PPE response, e.g., behavior of PPE to Z8 values. Example PPE response for the base design 303 is illustrated in graph 355 of FIG. 3C. The PPE responses 357a and 357b correspond to initial PPE responses (prior to optimization) of top pattern 304a and bottom pattern 304b, respectively, obtained for a nominal condition. The first PPE response 358 corresponds to the optimized top pattern 304a in which the PPE of the top pattern 304a is optimized for, or matches with, PPE_offset1 338 at Z8 value, Z8p 341, and b) a PPE response 356 of the optimized bottom pattern 304b in which the PPE of the bottom pattern 304b is optimized for, or matches with, the PPE_offset2 336 at Z8 value, Z8n 342. The cost function for optimizing the base design 303 based on the PPE response to Z8 value may be evaluated as follows:

$$( Equation 1 B )$$

$$Cost = {w}_{offset} [ {( {PPE}_{Z8p}^{t} - {PPE}_{offset 1} )}^{2} + {( {PPE}_{Z8n}^{b} - {PPE}_{offset 2} )}^{2} ] + EPE + MRC \_P enalty + sidelobe$$

where —w_{offset} is a weight factor added to adjust sensitivity,
   PPE_{Z8p}^{t} is PPE of the top pattern 304a at Z8p value 341 (positive value),
   PPE_{offset1} is a PPE value to which the PPE of the top pattern 304a is to be adjusted for Z8 value Z8p 341,
   PPE_{Z8n}^{b} is PPE of the bottom pattern 304b at Z8n value 342 (negative value),
   PPE_{offset2} is a PPE value to which the PPE of the bottom pattern 304b is to be adjusted for Z8 value Z8n 342,
   EPE is the EPE values for a complete process window,
   MRC_penalty is a penalty associated with mask rule check, which is used to verify whether a mask design conforms to specified standards, and
   sidelobe is representative of sidelobe artifacts caused in printing the device pattern.

The following paragraphs describe optimizing a metrology mark to have a matching aberration sensitivity with a given device pattern to be printed on a substrate. FIG. 5A is a block diagram of a system 500 for optimizing a metrology mark to have a matching aberration sensitivity with a given device pattern, in accordance with one or more embodiments. The system 500 includes a pattern optimizer 305 that is configured to optimize a metrology mark 503 for a device pattern 504 to generate an optimized metrology mark 513. As described above, metrology marks, such as TIS marks, OVL marks, alignment marks, or other marks, are used for monitoring aberration drift of an optical system (e.g., lens) of a lithographic system. A device pattern 504 may correspond to a target pattern to be printed on a substrate. The metrology marks and device patterns may have different aberration sensitivity trends and therefore, have different responses to adjustments of the optical parameters. The pattern optimizer 305 may optimize the metrology mark 503 by modifying the metrology mark 503 to have a matching aberration sensitivity with the device pattern 504.

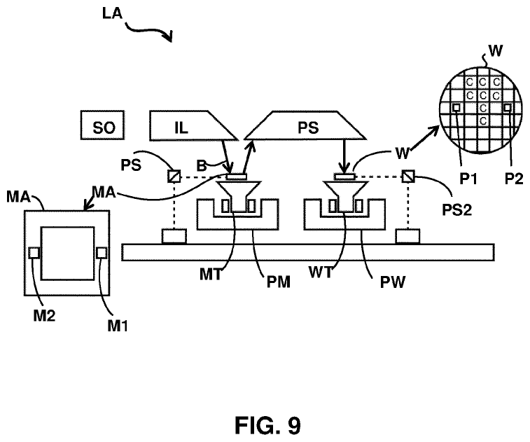

As an example, the metrology mark 503 may include a TIS mark 503. In some embodiments, TIS may be used to determine the lateral position and best focus position (e.g., horizontal and vertical position) of an image projected from the mask under the projection lens. TIS may be inset into a physical reference surface that is associated with the substrate table (e.g., table WTa of FIG. 9). According to one embodiment, two sensors may be placed on fiducial plates at diagonally opposite positions outside the area covered by the wafer W. The sensor may be mounted to the substrate-bearing surface of the substrate table (WTa) and may be used to directly determine the vertical and/or horizontal positions of the aerial image of the projected image. The TIS can be used as a measurement instrument that measures a location of an aerial image of an object mark in space and that measures a shape of the aerial image. The object mark may be placed on a reticle or on a reticle stage fiducial. The location information may be used to mathematically couple the reticle to the substrate table. The location information may be used to expose images on the substrate that are located at a best-focus (BF) position (z-position) and in a correct lateral position (overlay). The information regarding the shape of the aerial image may be used for machine set up, calibration and monitoring. In some embodiments, a simulation model may be used to simulate a TIS mark and TIS sensor topography to predict an alignment of the TIS mark at various positions of the substrate table with and without aberration of the optical system. A TIS alignment methods (e.g., TIS alignment fitting algorithm may be used determine a difference between the predicted alignment position and expected alignment position for determining an effect of the aberration sensitivity on the alignment of the TIS mark. According to embodiments of the present disclosure, the TIS mark may then be optimized to match the sensitivity of a device pattern as described below.

The pattern optimizer 305 may be configured to optimize the TIS mark 503 for the device pattern 504 based on an imaging characteristic behavior, such as CD response to focus. The pattern optimizer 305 may obtain a first CD response 527 of the TIS mark 503 for a given measurement point 507, and a second CD response 529 of the device pattern 504, as illustrated in graph 525 of FIG. 5B. In some embodiments, the first CD response 527, which describes how CD of the TIS mark 503 varies for different focus values, may be obtained using one or more simulation models such as an optics model, or a source model described at least with reference to FIG. 2, which can be physical models, heuristic models, or machine learning models. In some embodiments, the second CD response 529, which describes how CD of the device pattern 504 varies for different focus values, may be obtained using simulation models such as an optics model, a source model, or a resist model described at least with reference to FIG. 2. The pattern optimizer 305 may also obtain, based on the CD responses, the delta CD response to focus values for both the TIS mark 503 and the device pattern 504, as illustrated in graph 535. For example, a first delta CD response 536 corresponds to the TIS mark 503 and a second delta CD response 537 corresponds to the device pattern 504.

The pattern optimizer 305 may compute or evaluate a cost function to determine a difference between the aberration sensitivities of the TIS mark 503 and the device pattern 504 using the CD response of both designs as follows:

$$( Equation 2 A )$$

$$Cost = {w}_{offset} [ {( δ {CD}_{dfp}^{TIS} - {CD}_{offset - dfp} )}^{2} + {( δ {CD}_{dfnom}^{TIS} - {CD}_{offset - dfnom} )}^{2} + {( δ {CD}_{dfn}^{TIS} - {CD}_{offset - dfn} )}^{2} ] + {NCEPE}^{2} + MRC \_ penalty$$

where
   w_{offset} is a weight factor added to adjust sensitivity,
   δCD_{dfp}^{TIS} is delta CD of the TIS mark 503 at dfp focus value 532,
   CD_{offset-dfp} 546 is the difference between the CD of the device pattern 504 at dfp focus value 532 (e.g., a delta CD value of the device pattern at dfp) and a target CD of the device pattern,
   δCD_{dfnom}^{TIS} is delta CD of the TIS mark 503 at nominal condition focus value,
   CD_{offset-dfnom} 547 is the difference between the CD of the device pattern 504 at nominal condition focus value 531 and a target CD of the device pattern (e.g., a delta CD value of the device pattern at dfnom),
   δCD_{dfn}^{TIS} Par is delta CD of the TIS mark 503 at dfn focus value 530,
   CD_{offset-dfn} 548 is the difference between the CD of the device pattern 504 and the nominal condition CD at dfn focus value 530 (e.g., a delta CD value of the device pattern at dfn),
   NCEPE is the EPE value at nominal condition, and
   MRC_penalty is a penalty associated with mask rule check, which can be used to verify whether a mask design conforms to specified standards.

The pattern optimizer 305 may optimize the TIS mark 503 by reducing the terms—(δCD_{dfp}^{TIS}−CD_{offset-dfp}), (δCD_{dfnom}^{TIS}−CD_{offset-dfnom}) or (δCD_{dfn}^{TIS}−CD_{offset-dfn}), which are indicative of a difference between the aberration sensitivity of the TIS mark 503 and the device pattern 504. The pattern optimizer 305 may reduce the aberration sensitivity difference by modifying the TIS mark 503. In some embodiments, the pattern optimizer 305 may modify the TIS mark 503 by adjusting the dimensions (e.g., CD, or other dimensions) associated with the TIS mark 503, or by adding assist features to, or removing assist features from, the TIS mark 503. In some embodiments, the lower the cost, the more optimized is the resulting optimized TIS mark 513. The pattern optimizer 305 continues modifying the TIS mark 503 and evaluating the cost function with the imaging characteristics (e.g., CD) of the modified TIS mark 503 until the cost function is minimized (e.g., a threshold value is reached or a threshold number of iterations are performed), and outputs an optimized TIS mark 513 when the cost is minimized. In the optimized TIS mark 513, the pattern optimizer 305 has modified the CD of the pattern 505 of the TIS mark 503 (e.g., as illustrated by optimized pattern 515 in the optimized TIS mark 513), and added assist features 516 to the TIS mark 503. Note that while the TIS mark 503 includes a single pattern portion (e.g., pattern 505), the TIS mark 503 may include additional pattern portions. Further, note that while the assist features 516 are added external to the pattern 505, assist feature 517 is added internal to the pattern 505 (e.g., in optimized pattern 515), in some embodiments, the assist features may be added internally or externally to the pattern 505.

In some embodiments, the pattern optimizer 305 uses CTM optimization process in optimizing the TIS mark 503. A CTM optimization process may involve optimization of grey scale values using a gradient descent, or other optimization methods, so that a performance metric (e.g., EPE) of a lithographic apparatus is improved. The CTM optimization process is performed on a CTM image 514 (see, FIG. 5D) corresponding to the TIS mark 503 with the above cost function (e.g., Equation 2A) in an iterative manner. In each iteration, the cost function is evaluated, the TIS mark 503 is adjusted (e.g., dimensions of the TIS mark 503 are modified, assist features added to or removed from the TIS mark 503) to reduce the cost function. The CTM optimization process may continue until the cost function is minimized. After the cost function is minimized, the pattern optimizer 305 may extract the features from the optimized CTM image to generate the optimized TIS mark 513.

FIG. 5C shows a graph illustrating an imaging characteristic behavior of an optimized metrology mark in comparison with an imaging characteristic behavior of a device pattern for which the metrology mark is optimized, in accordance with one or more embodiments. As an example, the graph 555 shows a delta CD response 550 of the optimized TIS mark 513 in comparison with the second delta CD response 537 of the device pattern. Note that the difference between the CDs of the device pattern 504 and the optimized TIS mark 513 are minimized (or lesser than the difference indicated in graph 535), including at the selected focus values (e.g., dfn 530, dfnom 531, dfp 532). That is, the aberration sensitivity of the optimized TIS mark 513 matches with the aberration sensitivity of the device pattern 504.

FIG. 6A is a flow diagram of a method 600 for optimizing a metrology mark to have a matching aberration sensitivity with a given device pattern, in accordance with one or more embodiments. At process P601, a first aberration sensitivity of an input metrology mark (e.g., TIS mark 503) to a select optical parameter is obtained. In some embodiments, pattern optimizer 305 may be configured to execute a lithography simulation (e.g., using simulation models such as an optics model, an illuminator model or a resist model described at least with reference to FIG. 2) on the TIS mark 503 to obtain an imaging characteristic behavior for a select parameter, which is representative of the first aberration sensitivity. For example, the pattern optimizer 305 may obtain imaging characteristic behavior such as the first CD response 527, which is representative of the aberration sensitivity of the CD of the TIS mark 503 to focus parameter associated with an optical system of the lithography system. The input to process P601 may include parameters such as the TIS mark 503, the imaging characteristic (e.g., a CD, a PPE, an EPE, or another imaging characteristic) that may have to be optimized for a select optical parameter (e.g., focus, dose, Zernike, wavefront image, or other optical parameter associated with the optical system). The pattern optimizer 305 may obtain the imaging characteristic behavior for the specified parameters.

At process P602, a second aberration sensitivity of a device pattern 504 is obtained (e.g., in a way similar to first aberration sensitivity described above). For example, a second CD response 529, which is representative of the aberration sensitivity of the CD of the device pattern 504 to focus parameter associated with an optical system of the lithography system, is obtained.

At process P603, the TIS mark 503 is optimized by matching the second aberration sensitivity with the first aberration sensitivity to generate an optimized TIS mark 513. In some embodiments, the pattern optimizer 305 evaluates a cost function that determines aberration sensitivity difference between the TIS mark 503 and the device pattern 504 based on the aberration sensitivities of the TIS mark 503 and the device pattern 504. The TIS mark 503 is optimized by minimizing the cost function, as described at least with reference to FIG. 5A above and FIG. 6B below. After the cost function is minimized, the pattern optimizer 305 outputs the optimized TIS mark 513. The optimized TIS mark 513 may have an aberration sensitivity matching with the device pattern 504, as illustrated in graph 555 of FIG. 5C.

FIG. 6B is a flow diagram of a method 650 for optimizing a metrology mark using a cost function, in accordance with one or more embodiments. In some embodiments, the method 650 may be implemented as part of process P603 in method 600 of FIG. 6A. At process P604, a cost function is evaluated to determine a difference between the aberration sensitivities of the TIS mark 503 and the device pattern 504. For example, the pattern optimizer 305 evaluates the cost function, such as the one indicated by Equation 2A above, to determine the difference between the aberration sensitivity of the TIS mark 503 and the device pattern 504 at focus values, dfp 532, dfnom 531, or dfn 530, using the terms (δCD_{dfp}^{TIS}−CD_{offset-dfp}), (δCD_{dfnom}^{TIS}−CD_{offset-dfnom}) or (δCD_{dfn}^{TIS}−CD_{offset-dfn}), respectively.

At process P605, a CTM optimization process is performed to optimize the TIS mark 503. The CTM optimization process may involve optimization of grey scale values in the CTM image 514 corresponding to the TIS mark 503 so that a performance metric (e.g., EPE or other metric) of a lithographic apparatus is improved. The CTM optimization process is performed with the above cost function (e.g., Equation 2A) in an iterative manner. In the CTM optimization process, the TIS mark 503 is adjusted (e.g., dimensions of the TIS mark 503 are modified, assist features added to or removed from the TIS mark 503) to reduce the cost function.

The process P604 and P605 are performed iteratively until the cost function is minimized (e.g., cost does not reduce any more). During the evaluation, the pattern optimizer 305 may also adjust the weight of the cost function to adjust the sensitivity.

At process P606, after the cost function is minimized, the CTM image is processed to extract the features corresponding to the optimized TIS mark 513. For example, the CTM image is processed to extract the features 515, 516 and 517, which collectively form the optimized TIS mark 513.

Note that while the foregoing paragraphs describe optimizing the TIS mark 503 based on an imaging characteristic behavior, such as CD response to focus, the TIS mark 503 may be optimized for other imaging characteristic behavior as well. For example, the TIS mark 503 may be optimized for PPE response, e.g., behavior of PPE to Z8 values. The cost function for optimizing the TIS mark 503 based on the PPE response to Z8 value may be evaluated in a way similar to the Equation 1B above. Also, note that while the foregoing paragraphs describe optimizing a metrology mark such as a TIS mark 503, the methods can be implemented for optimizing other metrology targets, such as OVL marks, alignment marks, PARIS marks, or other marks.

Further, note that a portion of the cost function is customizable. The cost function may be denoted as follows:

$$Cost = CCF + {NCEPE}^{2} + MRC \_P enalty \qquad ( Equation 3 A )$$

where CCF is the custom cost function and be customized in various ways. For example, Equation 1A corresponds to a cost function that optimizes a design with respect to two focus values (dfp, and dfn) and therefore, the CCF portion of the Equation 1A has two terms—

$${w}_{offset} [ {( {CD}_{dfp}^{CD \_ t} - {CD}_{offset - dfp} )}^{2} + {( {CD}_{dfn}^{CD \_ b} {CD}_{offset - dfn} )}^{2} ]$$

Similarly, Equation 2A corresponds to a cost function that optimizes a metrology mark with respect to three focus values (e.g., dfp, dfnom, and dfn) and therefore, the CCF portion of the Equation 2A has three terms:

$${w}_{offset} [ {( δ {CD}_{dfp}^{TIS} - {CD}_{offset - dfp} )}^{2} + {( δ {CD}_{dfnom}^{TIS} - {CD}_{offset - dfnom} )}^{2} + {( δ {CD}_{dfn}^{TIS} - {CD}_{offset - dfn} )}^{2} ]$$

Similarly, the cost function based on PPE response may be denoted as:

$$Cost = CCF + EPE + {MRC}_{P enalty} + sidelobe \qquad ( Equation 3 B )$$

where CCF is the custom cost function and be customized in various ways.

For example, Equation 1B corresponds to a cost function that optimizes the metrology mark with respect to two Zernike values (Z8p, and Z8n) and therefore, the CCF portion of the Equation 1B has two terms:

$${w}_{offset} [ {( {PPE}_{Z8p}^{t} - {PPE}_{offset 1} )}^{2} + {( {PPE}_{Z8n}^{b} - {PPE}_{offset 2} )}^{2} ]$$

The optimized aberration sensitive pattern (e.g., optimized design 313 or optimized TIS mark 513) may be used for various purposes. For example, the optimized aberration sensitive metrology marks are incorporated into a mask design along with the device pattern, and a mask having the mask design may be used to transfer the mask design onto a substrate using a patterning process. In another example, the optimized aberration sensitive pattern may be used for simulation of a pattern printed on the substrate using data obtained by a detector in a substrate plane of the lithography system.

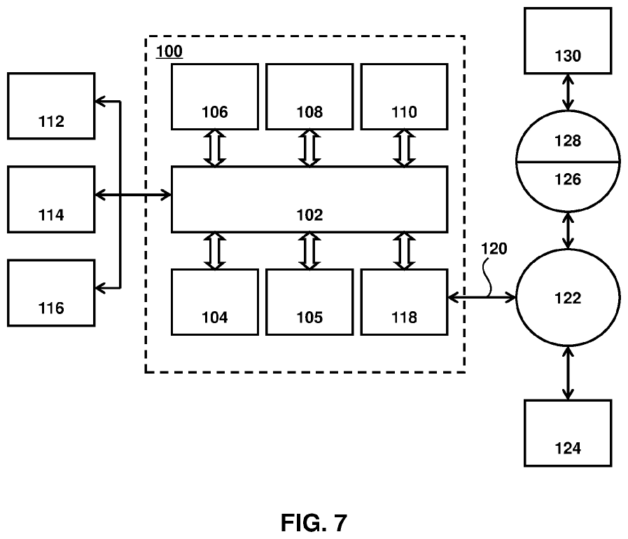

FIG. 7 is a block diagram that illustrates a computer system 100 which can assist in implementing the systems and methods disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

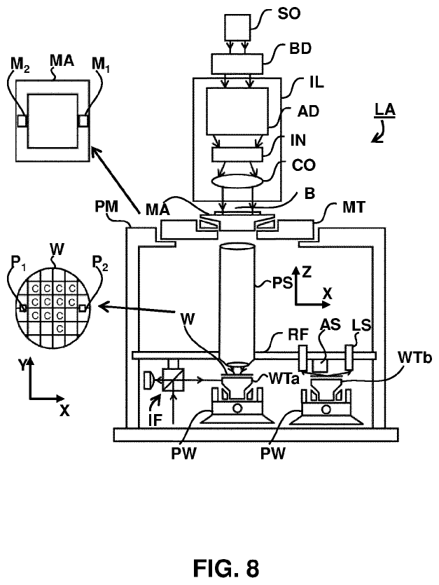

FIG. 8 schematically depicts an exemplary lithographic projection apparatus whose illumination source could be optimized utilizing the methods described herein. The apparatus comprises:
an illumination system IL, to condition a beam B of radiation. In this particular case, the illumination system also comprises a radiation source SO;
a first object table (e.g., mask table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 9 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g., so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 9. However, in the case of a wafer stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

FIG. 9 schematically depicts another exemplary lithographic projection apparatus LA whose illumination source could be optimized utilizing the methods described herein.

The lithographic projection apparatus LA includes:
a source collector module SO
an illumination system (illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

As here depicted, the apparatus LA is of a reflective type (e.g., employing a reflective mask). It is to be noted that because most materials are absorptive within the EUV wavelength range, the mask may have multilayer reflectors comprising, for example, a multi-stack of Molybdenum and Silicon. In one example, the multi-stack reflector has a 40-layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 9, the illuminator IL receives an extreme ultraviolet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 9, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LA could be used in at least one of the following modes:
1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.
2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.
3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

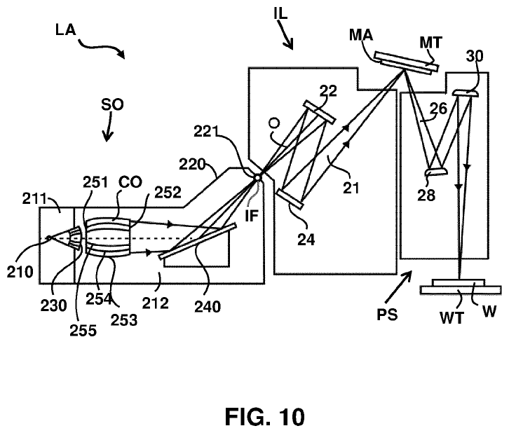

FIG. 10 shows the apparatus LA in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contaminant trap 230 may also include a gas barrier or a combination of a gas barrier and a channel structure. The contaminant trap or contaminant trap 230 further indicated herein at least includes a channel structure, as known in the art.

The collector chamber 212 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 10.

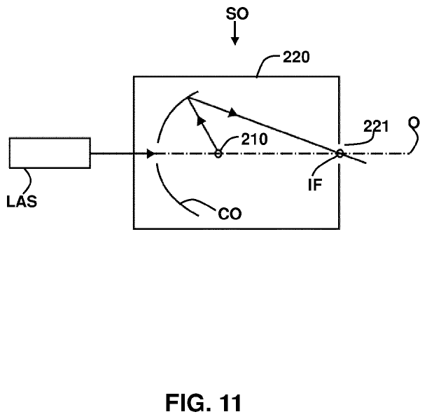

Collector optic CO, as illustrated in FIG. 11, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is preferably used in combination with a discharge produced plasma source, often called a DPP source.

Alternatively, the source collector module SO may be part of an LPP radiation system as shown in FIG. 11. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

Embodiments of the present disclosure can be further described by the following clauses.

1. A non-transitory computer-readable medium having instructions that, when executed by a computer, cause the computer to execute a method for optimizing a metrology target in a mask design used in a lithography system, the method comprising:
determining a first aberration sensitivity of a device pattern to a select optical parameter related to an optical system of a lithography system, wherein the device pattern corresponds to a target pattern to be printed on a substrate;
determining a second aberration sensitivity of a metrology target to the select optical parameter, wherein the metrology target is used to assist in printing the device pattern on the substrate; and
optimizing the metrology target by matching the first aberration sensitivity with the second aberration sensitivity to generate an optimized metrology target.

2. The computer-readable medium of clause 1, wherein optimizing the metrology target includes:
evaluating a cost function comprising an aberration sensitivity difference between the metrology target and the device pattern.

3. The computer-readable medium of clause 2, wherein the aberration sensitivity difference is determined from imaging characteristics data obtained using simulation of a lithography system or patterning process.

4. The computer-readable medium of clause 2, wherein the aberration sensitivity difference is determined based on an imaging characteristic of the metrology target and the device pattern.

5. The computer-readable medium of clause 4, wherein the imaging characteristic includes at least one of a critical dimension (CD), a pattern placement error (PPE), or an edge placement error (EPE).

6. The computer-readable medium of clause 2, wherein optimizing the metrology target includes minimizing the cost function.

7. The computer-readable medium of clause 2, wherein optimizing the metrology target includes:
adjusting an imaging characteristic of the metrology target to minimize the cost function.

8. The computer-readable medium of clause 7, wherein adjusting the imaging characteristic includes modifying a dimension of the metrology target.

9. The computer-readable medium of clause 7, wherein adjusting the imaging characteristic includes adding or removing assist features from the metrology target.

10. The computer-readable medium of clause 2, wherein the cost function further comprises at least one of (a) an EPE value for a nominal condition of dose and focus parameters of an optical system of a lithography system used to print the device pattern on the substrate, (b) EPE values for a given process window of the dose and focus parameters, (c) mask rule check constraints used in verifying a mask design that is used in printing the device pattern, or (d) sidelobe data representative of sidelobe artifacts caused in printing the device pattern.

11. The computer-readable medium of clause 1, wherein the select optical parameter includes at least one of a depth of focus value associated with an optical system of a lithography system used to print the device pattern on the substrate, a Zernike polynomial or a wavefront image associated with the optical system.

12. The computer-readable medium of clause 1, wherein determining the first aberration sensitivity of the device pattern includes:
obtaining a first set of imaging characteristic values for a first set of optical parameter values for the device pattern; and
determining the first aberration sensitivity based on the first set of imaging characteristic values and the first set of optical parameter values.

13. The computer-readable medium of clause 1, wherein determining the second aberration sensitivity of the metrology target includes:
obtaining a second set of wafer characteristic values for a second set of optical parameter values for the metrology target; and
determining the second aberration sensitivity based on the second set of wafer characteristic values and the second set of optical parameter values.

14. The computer-readable medium of clause 1, wherein determining the first aberration sensitivity and the second aberration sensitivity includes:
obtaining a first delta CD response comprising a first set of delta CD values of the device pattern for a first set of focus values, wherein the first delta CD response is representative of the first aberration sensitivity; and
obtaining a second delta CD response comprising a second set of delta CD values of the metrology target for the first set of focus values, wherein the second delta CD response is representative of the second aberration sensitivity.

15. The computer-readable medium of clause 14, wherein optimizing the metrology target includes:
computing a cost function comprising a first value and a second value,
   wherein the first value is representative of a difference between (a) a first delta CD value of the metrology target at a specified positive focus value, and (b) a first CD offset value that is representative of a second delta CD value of the device pattern at the specified positive focus value, and
   wherein the second value is representative of a difference between (a) a third delta CD value of the metrology target at a specified negative focus value, and (b) a second CD offset value that is representative of a fourth delta CD value of the device pattern at the specified negative focus value; and
minimizing the cost function.

16. The computer-readable medium of clause 1, wherein determining the first aberration sensitivity and the second aberration sensitivity includes:
obtaining a first PPE response comprising a first set of PPE values of the device pattern for a set of Zernike values, wherein the first PPE response is representative of the second aberration sensitivity; and
obtaining a second PPE response comprising a second set of PPE values of the metrology target for the set of Zernike values, wherein the second PPE response is representative of the second aberration sensitivity.

17. The computer-readable medium of clause 16, wherein optimizing the metrology target includes:
computing a cost function comprising a first term and a second term,
   wherein the first term is representative of a difference between (a) a first PPE value of the metrology target at a specified positive Zernike value, and (b) a first PPE offset value that is representative of a second PPE value of the device pattern to which a PPE of the metrology target is to be adjusted at the specified positive Zernike value, and
   wherein the second term is representative of a difference between (a) a third PPE value of the metrology target at a specified negative Zernike value, and (b) a second PPE offset value that is representative of a fourth PPE value of the device pattern to which a PPE of the metrology target is to be adjusted at the specified negative Zernike value; and
minimizing the cost function.

18. The computer-readable medium of clause 1, wherein the metrology target includes a transmission image sensor (TIS) mark.

19. The computer-readable medium of clause 1, wherein the metrology target includes at least one of an alignment mark or an overlay (OVL) mark.

20. The computer-readable medium of clause 1 further comprising:
generating a mask design using the optimized metrology target.

21. The computer-readable medium of clause 20 further comprising:
performing a patterning step using the mask design to print the device pattern on the substrate, or on a detector in a substrate plane, using a lithography system.

22. A non-transitory computer-readable medium having instructions that, when executed by a computer, cause the computer to execute a method for generating an aberration sensitive pattern in a mask design used in a lithography system, the method comprising:
obtaining a first imaging characteristic response of a first portion of a given design to a select optical parameter, wherein the given design includes one of (a) a device pattern that corresponds to a target pattern to be printed on a substrate, or (b) a metrology target used in printing the device pattern on the substrate, the first imaging characteristic response being representative of a first aberration sensitivity of the first portion;
obtaining a second imaging characteristic response of a second portion of the given design to the select optical parameter, the second imaging characteristic response being representative of a second aberration sensitivity of the second portion, wherein the first and second aberration sensitivities are related to an optical system of a lithography system;
obtaining a specified aberration sensitivity data to which the first and second aberration sensitivities are to be matched; and
optimizing the given design by matching the first aberration sensitivity and the second aberration sensitivity to the specified aberration sensitivity to generate an optimized pattern.

23. The computer-readable medium of clause 22, wherein the specified aberration sensitivity includes a specified image characteristic value for a specified optical parameter value.

24. The computer-readable medium of clause 22, wherein optimizing the given design includes:
computing a cost function comprising a difference between (a) the first aberration sensitivity and the specified aberration sensitivity, and (b) the second aberration sensitivity and the specified aberration sensitivity.

25. The computer-readable medium of clause 24, wherein the difference between the first aberration sensitivity is determined based on an imaging characteristic of the first portion.

26. The computer-readable medium of clause 25, wherein the imaging characteristic includes at least one of a critical dimension (CD), a pattern placement error (PPE), or an edge placement error (EPE).

27. The computer-readable medium of clause 24, wherein optimizing the given design includes minimizing the cost function.

28. The computer-readable medium of clause 24, wherein optimizing the given design includes:
adjusting an imaging characteristic of the given design to minimize the cost function.

29. The computer-readable medium of clause 28, wherein adjusting the imaging characteristic includes increasing or decreasing a dimension of the given design.

30. The computer-readable medium of clause 28, wherein adjusting the imaging characteristic includes adding assist features to an exterior of a given design or removing assist features from an interior of the given design.

31. The computer-readable medium of clause 22, wherein obtaining the first imaging characteristic response and the second imaging characteristic response includes:
obtaining a first CD response comprising a first set of CD values of the first portion for a first set of focus values; and
obtaining a second CD response comprising a second set of CD values of the second portion for the first set of focus values.

32. The computer-readable medium of clause 31, wherein optimizing the given design includes:
computing a cost function comprising a first term and a second term,
   wherein the first term is representative of a difference between (a) a first CD value of the first portion at a specified positive focus value, and (b) a first CD offset value that is representative of a second CD value to which a CD of the first portion is to be adjusted at the specified positive focus value, and
   wherein the second term is representative of a difference between (a) a third CD value of the second portion at a specified negative focus value, and (b) a second CD offset value that is representative of a fourth CD value to which a CD of the second portion is to be adjusted at the specified negative focus value; and
minimizing the cost function.

33. The computer-readable medium of clause 22, wherein obtaining the first imaging characteristic response and the second imaging characteristic response includes:
obtaining a first PPE response comprising a first set of PPE values of the first portion for a set of Zernike values; and
obtaining a second PPE response comprising a second set of PPE values of the second portion for the set of Zernike values.

34. The computer-readable medium of clause 33, wherein optimizing the given design includes:
computing a cost function comprising a first term and a second term, wherein:
   the first term is representative of a difference between (a) a first PPE value of the first portion at a specified positive Zernike value, and (b) a first PPE offset value that is representative of a second PPE value to which a PPE of the first portion is to be adjusted at the specified positive Zernike value, and
   the second term is representative of a difference between (a) a third PPE value of the second portion at a specified negative Zernike value, and (b) a second PPE offset value that is representative of a fourth PPE value to which a PPE of the second portion is to be adjusted at the specified negative Zernike value; and
minimizing the cost function.

35. The computer-readable medium of clause 22, wherein the given design includes a transmission image sensor (TIS) mark.

36. The computer-readable medium of clause 22, wherein the given design includes at least one of an alignment mark or an overlay (OVL) mark.

37. The computer-readable medium of clause 22 further comprising:
generating a mask design using the optimized pattern.

38. The computer-readable medium of clause 37 further comprising:
performing a patterning step using the mask design to print the device pattern on the substrate, or mask imaging on a detector, using a lithography system.

39. A method for optimizing a metrology target in a mask design used in a lithography system, the method comprising:
determining a first aberration sensitivity of a device pattern to a select optical parameter related to an optical system of a lithography system, wherein the device pattern corresponds to a target pattern to be printed on a substrate;
determining a second aberration sensitivity of a metrology target to the select optical parameter, wherein the metrology target is used to assist in printing the device pattern on the substrate; and
optimizing the metrology target by matching the first aberration sensitivity with the second aberration sensitivity to generate an optimized metrology target.

40. The method of clause 39, wherein optimizing the metrology target includes:
evaluating a cost function comprising an aberration sensitivity difference between the metrology target and the device pattern.

41. The method of clause 40, wherein the aberration sensitivity difference is determined from imaging characteristics data obtained using simulation of a lithography system or patterning process.

42. The method of clause 40, wherein the aberration sensitivity difference is determined based on an imaging characteristic of the metrology target and the device pattern.

43. The method of clause 42, wherein the imaging characteristic includes at least one of a critical dimension (CD), a pattern placement error (PPE), or an edge placement error (EPE).

44. The method of clause 40, wherein optimizing the metrology target includes minimizing the cost function.

45. The method of clause 40, wherein optimizing the metrology target includes:
adjusting an imaging characteristic of the metrology target to minimize the cost function.

46. The method of clause 45, wherein adjusting the imaging characteristic includes modifying a dimension of the metrology target.

47. The method of clause 45, wherein adjusting the imaging characteristic includes adding or removing assist features from the metrology target.

48. The method of clause 40, wherein the cost function further comprises at least one of (a) an EPE value for a nominal condition of dose and focus parameters of an optical system of a lithography system used to print the device pattern on the substrate, (b) EPE values for a given process window of the dose and focus parameters, (c) mask rule check constraints used in verifying a mask design that is used in printing the device pattern, or (d) sidelobe data representative of sidelobe artifacts caused in printing the device pattern.

49. The method of clause 39, wherein the select optical parameter includes at least one of a depth of focus value associated with an optical system of a lithography system used to print the device pattern on the substrate, a Zernike polynomial or a wavefront image associated with the optical system.

50. The method of clause 39, wherein determining the first aberration sensitivity of the device pattern includes:
obtaining a first set of imaging characteristic values for a first set of optical parameter values for the device pattern; and
determining the first aberration sensitivity based on the first set of imaging characteristic values and the first set of optical parameter values.

51. The method of clause 39, wherein determining the second aberration sensitivity of the metrology target includes:
obtaining a second set of wafer characteristic values for a second set of optical parameter values for the metrology target; and
determining the second aberration sensitivity based on the second set of wafer characteristic values and the second set of optical parameter values.

52. The method of clause 39, wherein determining the first aberration sensitivity and the second aberration sensitivity includes:
obtaining a first delta CD response comprising a first set of delta CD values of the device pattern for a first set of focus values, wherein the first delta CD response is representative of the first aberration sensitivity; and
obtaining a second delta CD response comprising a second set of delta CD values of the metrology target for the first set of focus values, wherein the second delta CD response is representative of the second aberration sensitivity.

53. The method of clause 52, wherein optimizing the metrology target includes:
computing a cost function comprising a first value and a second value,
   wherein the first value is representative of a difference between (a) a first delta CD value of the metrology target at a specified positive focus value, and (b) a first CD offset value that is representative of a second delta CD value of the device pattern at the specified positive focus value, and
   wherein the second value is representative of a difference between (a) a third delta CD value of the metrology target at a specified negative focus value, and (b) a second CD offset value that is representative of a fourth delta CD value of the device pattern at the specified negative focus value; and
minimizing the cost function.

54. The method of clause 39, wherein determining the first aberration sensitivity and the second aberration sensitivity includes:
obtaining a first PPE response comprising a first set of PPE values of the device pattern for a set of Zernike values, wherein the first PPE response is representative of the second aberration sensitivity; and
obtaining a second PPE response comprising a second set of PPE values of the metrology target for the set of Zernike values, wherein the second PPE response is representative of the second aberration sensitivity.

55. The method of clause 54, wherein optimizing the metrology target includes:
computing a cost function comprising a first term and a second term,
   wherein the first term is representative of a difference between (a) a first PPE value of the metrology target at a specified positive Zernike value, and (b) a first PPE offset value that is representative of a second PPE value of the device pattern to which a PPE of the metrology target is to be adjusted at the specified positive Zernike value, and
   wherein the second term is representative of a difference between (a) a third PPE value of the metrology target at a specified negative Zernike value, and (b) a second PPE offset value that is representative of a fourth PPE value of the device pattern to which a PPE of the metrology target is to be adjusted at the specified negative Zernike value; and
minimizing the cost function.

56. The method of clause 39, wherein the metrology target includes a transmission image sensor (TIS) mark.

57. The method of clause 39, wherein the metrology target includes at least one of an alignment mark or an overlay (OVL) mark.

58. The method of clause 39 further comprising:
generating a mask design using the optimized metrology target.

59. The method of clause 58 further comprising:
performing a patterning step using the mask design to print the device pattern on the substrate, or on a detector in a substrate plane, using a lithography system.

60. A method for generating an aberration sensitive pattern in a mask design used in a lithography system, the method comprising:
obtaining a first imaging characteristic response of a first portion of a given design to a select optical parameter, wherein the given design includes one of (a) a device pattern that corresponds to a target pattern to be printed on a substrate, or (b) a metrology target used in printing the device pattern on the substrate, the first imaging characteristic response being representative of a first aberration sensitivity of the first portion;
obtaining a second imaging characteristic response of a second portion of the given design to the select optical parameter, the second imaging characteristic response being representative of a second aberration sensitivity of the second portion, wherein the first and second aberration sensitivities are related to an optical system of a lithography system;
obtaining a specified aberration sensitivity data to which the first and second aberration sensitivities are to be matched; and
optimizing the given design by matching the first aberration sensitivity and the second aberration sensitivity to the specified aberration sensitivity to generate an optimized pattern.

61. The method of clause 60, wherein the specified aberration sensitivity includes a specified image characteristic value for a specified optical parameter value.

62. The method of clause 60, wherein optimizing the given design includes:
computing a cost function comprising a difference between (a) the first aberration sensitivity and the specified aberration sensitivity, and (b) the second aberration sensitivity and the specified aberration sensitivity.

63. The method of clause 62, wherein the difference between the first aberration sensitivity is determined based on an imaging characteristic of the first portion.

64. The method of clause 63, wherein the imaging characteristic includes at least one of a critical dimension (CD), a pattern placement error (PPE), or an edge placement error (EPE).

65. The method of clause 62, wherein optimizing the given design includes minimizing the cost function.

66. The method of clause 62, wherein optimizing the given design includes:
adjusting an imaging characteristic of the given design to minimize the cost function.

67. The method of clause 66, wherein adjusting the imaging characteristic includes increasing or decreasing a dimension of the given design.

68. The method of clause 66, wherein adjusting the imaging characteristic includes adding assist features to an exterior of a given design or removing assist features from an interior of the given design.

69. The method of clause 60, wherein obtaining the first imaging characteristic response and the second imaging characteristic response includes:
obtaining a first CD response comprising a first set of CD values of the first portion for a first set of focus values; and
obtaining a second CD response comprising a second set of CD values of the second portion for the first set of focus values.

70. The method of clause 69, wherein optimizing the given design includes:
computing a cost function comprising a first term and a second term,
   wherein the first term is representative of a difference between (a) a first CD value of the first portion at a specified positive focus value, and (b) a first CD offset value that is representative of a second CD value to which a CD of the first portion is to be adjusted at the specified positive focus value, and
   wherein the second term is representative of a difference between (a) a third CD value of the second portion at a specified negative focus value, and (b) a second CD offset value that is representative of a fourth CD value to which a CD of the second portion is to be adjusted at the specified negative focus value; and
minimizing the cost function.

71. The method of clause 60, wherein obtaining the first imaging characteristic response and the second imaging characteristic response includes:
obtaining a first PPE response comprising a first set of PPE values of the first portion for a set of Zernike values; and
obtaining a second PPE response comprising a second set of PPE values of the second portion for the set of Zernike values.

72. The method of clause 71, wherein optimizing the given design includes:
computing a cost function comprising a first term and a second term, wherein:
   the first term is representative of a difference between (a) a first PPE value of the first portion at a specified positive Zernike value, and (b) a first PPE offset value that is representative of a second PPE value to which a PPE of the first portion is to be adjusted at the specified positive Zernike value, and
   the second term is representative of a difference between (a) a third PPE value of the second portion at a specified negative Zernike value, and (b) a second PPE offset value that is representative of a fourth PPE value to which a PPE of the second portion is to be adjusted at the specified negative Zernike value; and
minimizing the cost function.

73. The method of clause 60, wherein the given design includes a transmission image sensor (TIS) mark.

74. The method of clause 60, wherein the given design includes at least one of an alignment mark or an overlay (OVL) mark.

75. The method of clause 60 further comprising:
generating a mask design using the optimized pattern.

76. The method of clause 75 further comprising:
performing a patterning step using the mask design to print the device pattern on the substrate, or mask imaging on a detector, using a lithography system.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1.-16. (canceled)

17. A non-transitory computer readable medium having instructions therein, the instructions, when executed by a computer system, configured to cause the computer system to at least:
obtain a first imaging characteristic response of a first portion of a given design to a select optical parameter, wherein the given design includes one of (a) a device pattern that corresponds to a target pattern to be printed on a substrate, or (b) a metrology target used in printing the device pattern on the substrate, the first imaging characteristic response being representative of a first aberration sensitivity of the first portion;
obtain a second imaging characteristic response of a second portion of the given design to the select optical parameter, the second imaging characteristic response being representative of a second aberration sensitivity of the second portion, wherein the first and second aberration sensitivities are related to an optical system of a lithography system;
obtain specified aberration sensitivity data to which the first and second aberration sensitivities are to be matched; and
optimize the given design by matching the first aberration sensitivity and the second aberration sensitivity to the specified aberration sensitivity to generate an optimized pattern.

18. The computer readable medium of claim 17, wherein the specified aberration sensitivity data includes a specified image characteristic value for a specified optical parameter value.

19. The computer readable medium of claim 17, wherein the instructions configured to cause the computer system to optimize the given design are further configured to cause the computer system to compute a cost function comprising a difference between (a) the first aberration sensitivity and the specified aberration sensitivity, and (b) the second aberration sensitivity and the specified aberration sensitivity.

20. The computer readable medium of claim 19, wherein the difference between the first aberration sensitivity and the specified aberration sensitivity is determined based on an imaging characteristic of the first portion.

21. The computer readable medium of claim 20, wherein the imaging characteristic includes at least one selected from: a critical dimension (CD), a pattern placement error (PPE), or an edge placement error (EPE).

22. The computer readable medium of claim 19, wherein the instructions configured to cause the computer system to optimize the given design are further configured to cause the computer system to adjust an imaging characteristic of the given design based on the cost function by increasing or decreasing a dimension of the given design.

23. The computer readable medium of claim 19, wherein the instructions configured to cause the computer system to optimize the given design are further configured to cause the computer system to adjust an imaging characteristic of the given design by adding one or more assist features to an exterior of a given design or removing one or more assist features from an interior of the given design.

24. The computer readable medium of claim 17, wherein the given design includes a transmission image sensor (TIS) mark.

25. A non-transitory computer readable medium having instructions therein, the instructions, when executed by a computer system, configured to cause the computer system to at least:
determine a first aberration sensitivity of a device pattern to a select optical parameter related to an optical system of a lithography system, wherein the device pattern corresponds to a target pattern to be printed on a substrate;
determine a second aberration sensitivity of a metrology target to the select optical parameter, wherein the metrology target is used to assist in printing the device pattern on the substrate; and
optimize the metrology target by matching the first aberration sensitivity with the second aberration sensitivity to generate an optimized metrology target, wherein the metrology target comprises a transmission image sensor (TIS) mark.

26. The computer readable medium of claim 25, wherein the instructions configured to cause the computer system to optimize the metrology target are further configured to cause the computer system to evaluate a cost function comprising an aberration sensitivity difference between the metrology target and the device pattern.

27. The computer readable medium of claim 26, wherein the aberration sensitivity difference is determined from imaging characteristic data obtained using a simulation of a lithography system or patterning process, and wherein the aberration sensitivity difference is determined based on an imaging characteristic of the metrology target and the device pattern, wherein the imaging characteristic includes at least one selected from: a critical dimension (CD), a pattern placement error (PPE), or an edge placement error (EPE).

28. The computer readable medium of claim 26, wherein the instructions configured to cause the computer system to optimize the metrology target are further configured to cause the computer system to adjust an imaging characteristic of the metrology target based on the cost function, wherein adjustment of the imaging characteristic includes modification of a dimension of the metrology target, or addition or removal of one or more assist features from the metrology target.

29. The computer readable medium of claim 25, wherein the select optical parameter includes at least one selected from: a depth of focus value associated with an optical system of a lithography system used to print the device pattern on the substrate, a Zernike polynomial or a wavefront image associated with the optical system.

30. The computer readable medium of claim 25, wherein the instructions configured to cause the computer system to determine the first aberration sensitivity and the second aberration sensitivity are further configured to cause the computer system to:
obtain a first delta imaging characteristic response comprising a first set of delta imaging characteristic values of the device pattern for a first set of focus values, wherein the first delta imaging characteristic response is representative of the first aberration sensitivity; and
obtain a second delta imaging characteristic response comprising a second set of delta imaging characteristic values of the metrology target for the first set of focus values, wherein the second delta imaging characteristic response is representative of the second aberration sensitivity.

31. The computer readable medium of claim 30, wherein the instructions configured to cause the computer system to optimize the metrology target are further configured to cause the computer system to:
compute a cost function comprising a first value and a second value, wherein the first value is representative of a difference between (a) a first delta imaging characteristic value of the metrology target at a specified positive focus value, and (b) a first imaging characteristic offset value that is representative of a second delta imaging characteristic value of the device pattern at the specified positive focus value, and wherein the second value is representative of a difference between (a) a third delta imaging characteristic value of the metrology target at a specified negative focus value, and (b) a second imaging characteristic offset value that is representative of a fourth delta imaging characteristic value of the device pattern at the specified negative focus value; and
minimize the cost function.

32. The computer readable medium of claim 25, wherein the instructions configured to cause the computer system to determine the first aberration sensitivity and the second aberration sensitivity are further configured to cause the computer system to:
obtain a first imaging characteristic response comprising a first set of imaging characteristic values of the device pattern for a set of Zernike values, wherein the first imaging characteristic response is representative of the second aberration sensitivity; and
obtain a second characteristic response comprising a second set of characteristic values of the metrology target for the set of Zernike values, wherein the second characteristic response is representative of the second aberration sensitivity.

33. A method comprising:
obtaining a first imaging characteristic response of a first portion of a given design to a select optical parameter, wherein the given design includes one of (a) a device pattern that corresponds to a target pattern to be printed on a substrate, or (b) a metrology target used in printing the device pattern on the substrate, the first imaging characteristic response being representative of a first aberration sensitivity of the first portion;
obtaining a second imaging characteristic response of a second portion of the given design to the select optical parameter, the second imaging characteristic response being representative of a second aberration sensitivity of the second portion, wherein the first and second aberration sensitivities are related to an optical system of a lithography system;
obtaining specified aberration sensitivity data to which the first and second aberration sensitivities are to be matched; and
optimizing, by a hardware computer system, the given design by matching the first aberration sensitivity and the second aberration sensitivity to the specified aberration sensitivity to generate an optimized pattern.

34. The method of claim 33, wherein the specified aberration sensitivity data includes a specified image characteristic value for a specified optical parameter value.

35. The method of claim 33, wherein optimizing the given design includes computing a cost function comprising a difference between (a) the first aberration sensitivity and the specified aberration sensitivity, and (b) the second aberration sensitivity and the specified aberration sensitivity.

36. The method of claim 33, wherein the imaging characteristic includes at least one selected from: a critical dimension (CD), a pattern placement error (PPE), or an edge placement error (EPE).
